(19) United States
(12) Patent Application Publication
(10) Pub. No.: US 2015/0115427 A1
(43) Pub. Date: Apr. 30, 2015

(54) PACKAGE STRUCTURE AND PACKAGING METHOD THEREOF

(71) Applicant: SHENNAN CIRCUITS CO., LTD., Guangdong (CN)

(72) Inventors: Guanhua Li, Guangdong (CN); Jing Jiang, Guangdong (CN); Qinwei Peng, Guangdong (CN)

(21) Appl. No.: 14/000,058

(22) PCT Filed: May 18, 2012
(86) PCT No.: PCT/CN12/75753

§ 371 Date: Aug. 16, 2013

(51) Int. Cl. H01L 23/64; H01L 23/50; H01L 23/00; H01L 23/48

(52) U.S. Cl. CPC H01L 23/645; H01L 23/481; H01L 23/50; H01L 24/89
USPC 257/685; 438/121

(57) ABSTRACT

A package structure and a packaging method thereof are provided, in which an inductor is integrated into a substrate so as to save a packaging space and thus improve the integration level and packaging effect of the system. The package structure includes a substrate, wherein a first metal enclosing structure and a second metal enclosing structure are provided on the substrate and are connected through a connecting hole in the substrate so as to form a helical

### FIELD OF THE INVENTION

The present application relates to the field of mechanical package, and in particular to a package structure and a packaging method thereof.

### BACKGROUND OF THE INVENTION

A system in package (SiP) refers to a system packaging manner in which a number of electronic elements (e.g., microprocessor, memory, micro-electromechanical system, optical device, and passive electronic element, etc.) are integrated together when being packaged.

With the higher and higher requirements of users on integration level of electronic elements, the SiP technology is widely used. In the prior art, when some passive electronic elements need to be integrated in a SiP, the produced passive electronic elements will be welded onto a substrate by means of surface mounted technology (SMT) at first, and then packaged together with other devices into one piece.

For example, when an inductor needs to be integrated into a system, the inductor having a constant inductance amount will be directly embedded into the substrate according to the user's requirements so as to be packaged.

However, the inductor may sometimes go beyond the allowable dimensional range for a packaging body, or different inductance amount may be required during practical application of users. For this purpose, in the SiP of the prior art, the dimension of the packaging body often has to be increased, or a number of inductors having various inductance mounts have to be packaged to meet the user's requirements. However, it will take up a large space, thereby affecting the integration level and packaging effect of the system.

### SUMMARY OF THE INVENTION

There are provided in embodiments of the present application a package structure and a packaging method thereof which can save a packaging space and thus improve the integration level and packaging effect of the system.

A package structure is provided according to an embodiment of the present application, and the package structure includes a substrate;

wherein a first metal enclosing structure and a second metal enclosing structure are provided on the substrate; and

the first metal enclosing structure and the second metal enclosing structure are connected through a connecting hole in the substrate to form a helical coil.

Optionally, a groove may be further provided in the substrate;

the first metal enclosing structure may be located at the top of the groove, and the second metal enclosing structure may be located at the bottom of the groove; and

the helical coil may be formed around the groove.

Optionally, the second metal enclosing structure may include several metal windings and several metal bonding parts;

the metal windings may be provided at the bottom of the groove;

the metal bonding parts may be formed by extending the metal windings through the connecting hole in the substrate from a side surface of the groove to a surface of the substrate, the metal bonding parts may be distributed, on both sides of a surface of the groove;

the first metal enclosing structure may include several metal leads; and

the metal bonding parts on both sides of the surface of the groove may be connected by the metal leads, so that a passage is formed between any two connected metal bonding parts.

Optionally, the metal windings provided at the bottom of the groove may all be parts of the same helical coil, and

two ends of each of the metal windings may extend from two side surfaces of the groove to the surface of the substrate respectively, so as to form two metal bonding parts symmetrically distributed on both sides of the surface of the groove.

Optionally, the metal windings provided at the bottom of the groove may be parts of different helical coils; and

two ends of each of the metal windings may extend from two side surfaces of the groove to the surface of the substrate respectively, so as to form two metal bonding parts symmetrically distributed on both sides of the surface of the groove.

Optionally, two ends of each of the metal windings may extend from two side surfaces of the groove to the surface of the substrate respectively, so as to form 2N metal bonding parts symmetrically distributed on both sides of the surface of the groove, where N is a positive integer greater than 1; and

N metal bonding parts located on the same side of the surface of the groove may be distributed on the same surface, or distributed on different stepped surfaces.

Optionally, the substrate may include a first ink layer, a second ink layer, a first circuit layer, a second circuit layer and a core board layer;

the groove may be located in the core board layer, the core board layer may be an insulating layer;

the metal windings may be located at the second circuit layer at the bottom of the core board layer, the metal bonding parts may be located at the first circuit layer at the top of the core board layer;

the connecting hole may extend through the core board layer to connect the metal windings and the metal bonding parts; and

a surface of the first circuit layer may be coated with the first ink layer, a surface of the second circuit layer may be coated with the second ink layer.

Optionally, the first metal enclosing structure may include several metal windings and several metal bonding parts;

the metal windings may be provided at the top of the groove;

the metal bonding parts may be formed by extending the metal windings through the connecting hole in the substrate from the side surface of the groove to the surface of the substrate, the metal bonding parts are distributed on both sides of the surface of the groove;

the second metal enclosing structure may include several metal leads; and

the metal bonding parts on both sides of the surface of the groove may be connected by the metal leads, so that a passage is formed between any two connected metal bonding parts.

Optionally, the first metal enclosing structure may include upper surface metal windings, upper surface metal bonding parts and upper surface metal leads;

the upper surface metal windings are provided on side surfaces of the groove;

the upper surface metal bonding parts are formed by extending the upper surface metal windings through the connecting hole in the substrate to an upper surface of the substrate, the upper surface metal bonding parts are distributed on both sides of the upper surface of the substrate;

the upper surface metal bonding parts on both sides of the upper surface of the substrate are connected by the upper surface metal leads;

the second metal enclosing structure includes lower surface metal windings, lower surface metal bonding parts and lower surface metal leads;

the lower surface metal windings are provided on side surfaces of the groove;

the lower surface metal bonding parts are formed by extending the lower surface metal windings through the connecting hole in the substrate to a lower surface of the substrate, the lower surface metal bonding parts are distributed on both sides of the lower surface of the substrate; and

the lower surface metal bonding parts on both sides of the lower surface of the substrate are connected by the lower surface metal leads.

Optionally, the first metal enclosing structure may include a first set of metal windings;

the first set of metal windings may be provided at the top of the groove, and enclose the groove from an upper half of the groove;

the second metal enclosing structure may include a second set of metal windings;

the second set of metal windings may be provided at the bottom of the groove, and enclose the groove from a lower half of the groove; and

the first set of metal windings and the second set of metal windings may be mated such that a helical coil is formed around the groove when the first set of metal windings and the second set of metal windings are connected.

Optionally, the same helical coil or at least two helical coils may be formed when the first set of metal windings and the second set of metal windings are connected.

Optionally, the first metal enclosing structure may further include at least a third set of metal windings located at a circuit layer different from that of the first set of metal windings;

the third set of metal windings may be provided at the top of the groove, and enclose the groove from the upper half of the groove;

the second metal enclosing structure may further include at least a fourth set of metal windings located at a circuit layer different from that of the second set of metal windings;

the fourth set of metal windings may be provided at the bottom of the groove, and enclose the groove from the lower half of the groove; and

the third set of metal windings and the fourth set of metal windings may be mated such that another helical coil is formed around the groove when the thud set of metal windings and the fourth set of metal windings are connected.

Optionally, the substrate may include a first ink layer, a second ink layer, a first circuit layer, as second circuit layer, a core board layer and a filling layer;

the groove may be located in the core board layer, the core board layer may be an insulating layer;

the filling layer may be located at the top of the groove, the filling layer may be an insulating layer;

the first set of metal windings may be located at the first circuit layer at the top of the core board layer, the second set of Metal windings may be located at the second circuit layer at the bottom of the core board layer;

the connecting hole may extend through the core board layer to connect the first set of metal windings and the second set of metal windings; and

a surface of the first circuit layer may be coated with the first ink layer, a surface of the second circuit layer may be coated with the second ink layer.

Optionally, several pairs of metal connecting parts electrically connected with the helical coil may be provided on a surface of the substrate.

Optionally, the package structure may further include:

a controlling apparatus provided on the substrate;

wherein the controlling apparatus is connected to the metal connecting parts so as to control the inductance amount output from the helical coil.

Optionally, the package structure may further include:

an inductive core body provided in the groove.

A packaging method according to an embodiment of the present application, including:

processing, a substrate to form it connecting hole in the substrate;

providing a first metal enclosing structure and a second metal enclosing structure on the substrate,

wherein the first metal enclosing structure and the second metal enclosing structure are connected through the connecting hole in the substrate to form a helical coil; and

packaging the substrate and other devices on the substrate wholly or partly to form a package body.

Optionally, the packaging method may further include:

processing the substrate to form as groove in the substrate;

wherein providing a first metal enclosing structure and a second metal enclosing structure on the substrate includes:

providing the second metal enclosing structure at the bottom of the groove, and providing the first metal enclosing structure at the top of the groove; and

wherein the helical coil is formed around the groove.

Optionally, the second metal enclosing structure may include several metal windings and several metal bonding parts, and the fast metal enclosing structure may include several metal leads;

providing the second metal enclosing structure at the bottom of the groove and providing the first metal enclosing structure at the top of the groove includes:

providing a plurality of metal windings at the bottom of the groove, extending the metal windings from a side surface of the groove through the connecting hole in the substrate to a surface of the substrate so as to form a plurality of metal bonding parts, wherein the metal bonding parts are distributed on both sides of a surface of the groove; and

connecting the metal bonding parts on both sides of the surface of the groove by using the metal leads to form a helical coil, so that a passage is formed between any two connected metal bonding parts.

Optionally, the first metal enclosing structure includes a plurality of metal windings and a plurality of metal bonding parts, and the second metal enclosing structure includes a plurality of metal leads;

providing the second metal enclosing structure at the bottom of the groove and providing the first metal enclosing structure at the top of the groove includes:

providing a plurality of metal windings at the top of the groove, extending the metal windings from a side surface of the groove through the connecting hole in the substrate to a surface of the substrate so as to form a plurality of metal bonding parts, wherein the metal bonding parts are distributed on both sides of a surface of the groove; and

connecting the metal bonding parts on both sides of the surface of the groove by using the metal leads to form a helical coil, so that a passage is formed between any two connected metal bonding parts.

Optionally, the first metal enclosing structure includes upper surface metal windings, upper surface metal bonding parts and upper surface metal leads; the second metal enclosing structure includes lower surface metal windings, lower surface metal bonding parts and lower surface metal leads;

providing the second metal enclosing structure at the bottom of the groove and providing the first metal enclosing structure at the top of the groove includes:

providing the upper surface metal windings on side surfaces of the groove, extending the upper surface metal windings through the connecting hole in the substrate to an upper surface of the substrate so as to form the upper surface metal bonding parts, wherein the upper surface metal bonding parts are distributed on both sides of the upper surface of the substrate;

connecting the upper surface metal bonding parts on both sides of the upper surface of the substrate by using the upper surface metal leads;

providing the lower surface metal windings on side surfaces of the groove, extending the lower surface metal windings through the connecting hole in the substrate to a lower surface of the substrate so as to form the lower surface metal bonding parts, wherein the lower surface metal bonding parts are distributed on both sides of the lower surface of the substrate; and

connecting the lower surface metal bonding parts on both sides of the lower surface of the substrate by using the lower surface metal leads.

Optionally, the first metal enclosing structure includes a first set of metal windings, the second metal enclosing structure includes a second set of metal windings;

providing the second metal enclosing structure at the bottom of the groove and providing the first metal enclosing structure at the top of the groove includes:

providing the first set of metal windings at the top of the groove, so that the first set of metal windings enclose the groove from the upper half of the groove, and providing the second set of metal windings at the bottom of the groove, so that the second set of metal windings enclose the groove from the lower half of the groove;

wherein the first set of metal windings and the second set of metal windings are mated such that a helical coil i formed around the groove when the first set of metal windings and the second set of metal windings are connected.

Optionally, the method may further include:

providing, on a surface of the substrate, a plurality of pairs of metal connecting parts electrically connected with the helical coil.

Optionally, the method may further include:

providing a controlling apparatus on the substrate, and connecting the controlling apparatus with the metal connecting parts, so that the controlling apparatus controls the inductance amount output from the helical coil.

Optionally, the method may further include:

fixing an inductive core body in the groove.

It can be seen from the above technical solutions that the embodiments of the present application have the following advantages.

In the embodiments of the present application, the first metal enclosing structure and the second metal enclosing structure are provided on the substrate, and the first metal enclosing structure and the second metal enclosing structure are connected through the connecting hole in the substrate so as to form the helical coil, thus achieving the function of an inductor.

After forming the helical coil, a user can determine the length of the helical coil connected into as circuit depending on the actual requirements, so as to obtain desired amount of inductance. Since the embodiments of the present application can meet user's requirements on various inductance amounts, the packaging space can be saved, thus improving the integration level and packaging effect of the system.

### BRIEF DESCRIPTION OF THE DRAWINGS

FIG. 1 is a schematic view of a first embodiment of the package structure of the present application;

FIG. 2 is as schematic view of as second embodiment of the package structure of the present application;

FIG. 3 is as schematic view of a third embodiment of the package structure of the present application;

FIG. 4 is a schematic view of as fourth embodiment of the package structure of the present application;

FIG. 5 is a schematic view of a fifth embodiment of the package structure of the present application;

FIG. 6 is a schematic view of a sixth embodiment of the package structure if the present application;

FIG. 7 is a schematic view of a seventh embodiment of the package structure of the present application;

FIG. 8 is a schematic view showing the packaging effect of the seventh embodiment of the package structure of the present application;

FIG. 9 is a schematic view of an eighth embodiment of the package structure of the present application;

FIG. 10 is a schematic view of a ninth embodiment of the package structure of the present application;

FIG. 11 is a schematic view showing the packaging effect of the ninth embodiment of the package structure of the present application;

FIG. 12 is a schematic view of an embodiment of the packaging method of the present application;

FIG. 13 is a schematic view of amber embodiment of the packaging method of the present application;

FIG. 14 is a schematic view of a first stage of a packaging process of the present application;

FIG. 15 is a schematic view of a second stage of a packaging process of the present application;

FIG. 16 is a schematic view of a first application scene of the package structure of the present application;

FIG. 17 is a schematic view of a second application scene of the package structure of the present application;

FIG. 18 is a schematic view of a third application scene of the package structure of the present application; and

FIG. 19 is a schematic view of a fourth application scene of the package structure of the present application.

### DETAILED DESCRIPTION OF THE INVENTION

There are provided in an embodiment of the present application a package structure and a packaging method thereof, which can package passive electronic elements with variable parameters and save the packaging space and increase the integration level and packaging effect of the system.

The package structure in this embodiment may include a substrate; wherein

a first metal enclosing structure and a second metal enclosing structure are provided on the substrate; and

the first metal enclosing structure and the second metal enclosing structure are connected through a connecting hole in the substrate so as to form a helical coil, thus achieving the function of an inductor.

In this embodiment, a groove for holding an inductive core body may be provided in the substrate, or no groove may be provided in the substrate.

When no groove is provided, the first metal enclosing structure and the second metal enclosing structure are located at the upper portion and the lower portion of the substrate respectively.

When a groove is provided, the first metal enclosing structure may be located at the top of the groove, and the second metal enclosing structure may be located at the bottom of the groove.

In practical applications, whether it is necessary to provide a groove may be determined depending on requirements, and thus the position relationship between the first metal enclosing structure and the second metal enclosing structure may be determined.

In practical applications, the first metal enclosing structure and the second metal enclosing structure can be implemented in many manners which can be explained by way of the following two examples.

First, the first metal enclosing structure is an out-of-substrate connecting structure, and the second metal enclosing structure is an in-substrate connecting structure.

In this embodiment, forming the lower-half metal enclosure for the groove by the second metal enclosing structure is implemented by providing metal windings in the substrate, and Riming the upper-half metal enclosure for the groove by the first metal enclosing structure is implemented by bonding metal leads on the surface of the substrate.

Specifically, the second metal enclosing structure may include several metal windings and several metal bonding parts, wherein the metal windings are provided at the bottom of the groove; and the metal bonding parts are formed by extending the metal windings from a side surface of the groove through a connecting hole in the substrate to a surface of the substrate, and are distributed on both sides of a surface of the groove; and

correspondingly, the first metal enclosing structure may include several metal leads; and the metal bonding parts on both sides of the surface of the groove are connected by the metal leads, so that a passage is formed between any two connected metal bonding parts.

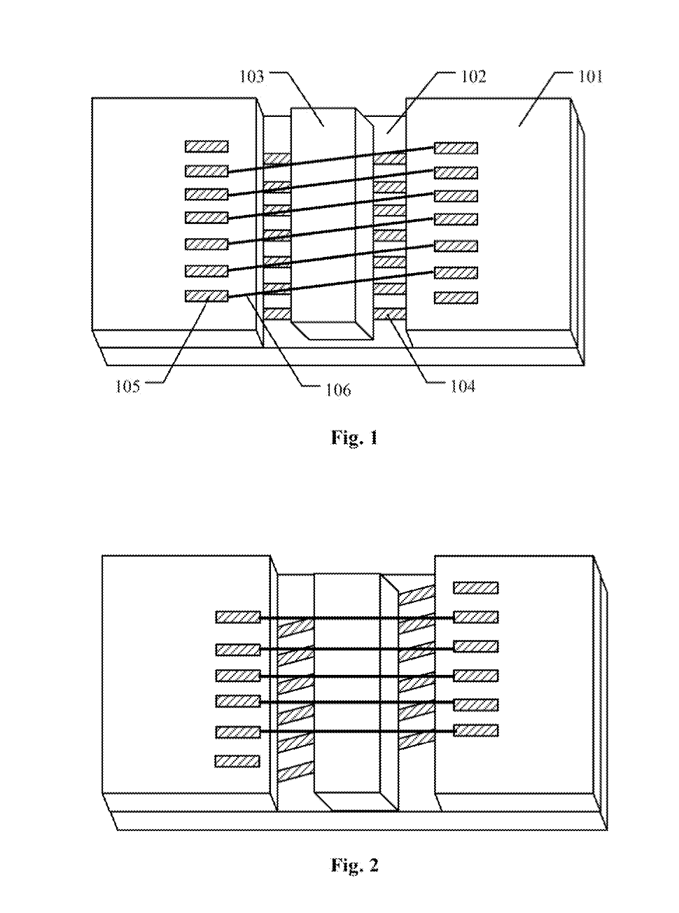

A detailed explanation will be made in conjunction with the accompanying drawings below. Referring to FIG. 1, a first embodiment of the package structure of the present application includes:

a substrate 101;

a groove 102 provided in the substrate 101;

several metal windings 104 provided at the bottom of the groove 102, wherein the metal windings 104 extend from a side surface of the groove 102 through connecting holes in the substrate 101 to a surface of the substrate 101 so as to form several metal bonding parts 105, the metal bonding parts 105 are distributed on both sides of a surface of the groove 102; and the metal bonding parts 105 on both sides of the surface of the groove 102 are connected by metal leads 106 so as to form a helical coil, so that a passage is formed between any two connected metal bonding parts 105.

It should be noted that, in order to increase the inductance amount, the package structure in this embodiment may further include an inductive core body 101 The inductive core body 103 may be provided in the groove 102. It can be understood that no inductive core body 103 may be provided in practical applications, which will not be specifically limited herein.

In order to form a helical coil of an inductor, when the metal bonding parts are connected using metal leads, the metal leads may be connected in a skew (misaligned) manner, or the metal windings may be provided in a skew manner. Accordingly, the metal windings 104 may be arranged in various manners, one of which is shown in FIG. 1. In FIG. 1, each metal winding may be approximately perpendicular to the inductive core body 103. It can be understood that other arrangement manners may also be used in practical applications, for example, referring to FIG. 2. The embodiment shown in FIG. 2 is a second embodiment of the package structure of the present application, and as compared with the first embodiment shown in FIG. 1, the difference only lies in the arrangement manner of the metal windings and the connection manner of the metal leads.

In the above solutions described in conjunction with FIGS. 1 and 2, the metal windings and the metal leads are of a single winding structure, that is, all of the metal windings and the metal leads form a same coil. In such a winding structure, the metal windings provided at the bottom of the groove all are parts of the same helical coil. Then, two ends of each of the metal windings extend from two side surfaces of the groove to a surface of the substrate, so as to form two metal bonding parts symmetrically distributed on both sides of the surface of the groove.

It should be understood that, in practical applications, in addition to the single winding structure, a multifilar winding structure or a multilayer winding structure may also be possible.

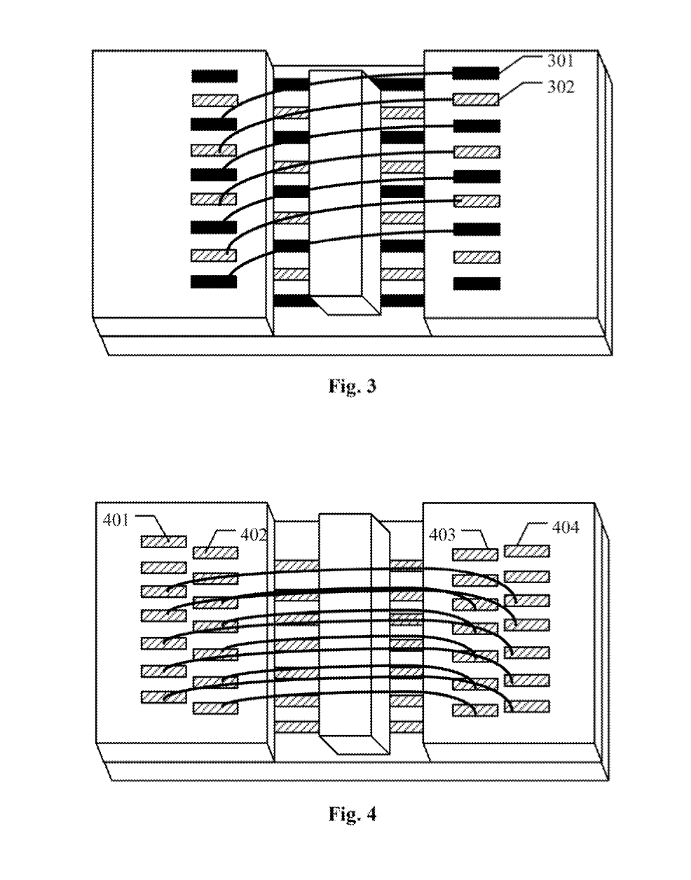

Specifically, when the metal windings and the metal leads are of the multifilar winding structure, please make a reference to FIG. 3 showing a third embodiment of the package structure of the present application.

The metal windings provided at the bottom of the groove form different helical coils, and metal bonding parts, which are formed by two ends of the metal windings of the different helical coils extending from two side surfaces of the groove to a surface of the substrate respectively, also form the different helical coils. That is, a metal bonding part 301 and a metal bonding part 302 as shown in FIG. 3 form different helical cods respectively, such that actually two different coils are provided around the groove. It should be understood that two coils are only described as an example herein, and more coils can be used in practical applications, which will not be limited herein.

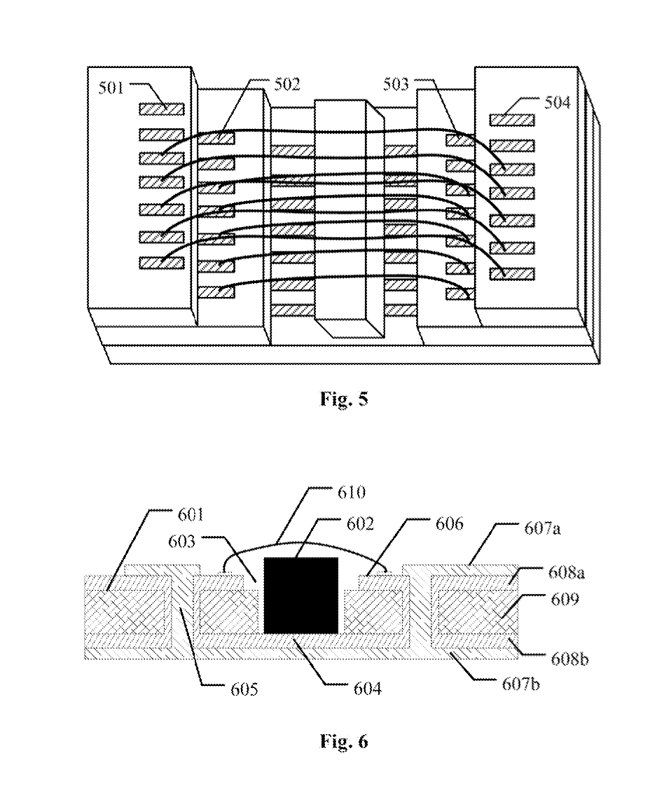

When the metal Windings and the metal leads are of the multilayer winding structure, please make a reference to FIGS. 4 and 5. FIG. 4 shows a fourth embodiment of the package structure of the present application, and FIG. 5 shows a fifth embodiment of the package structure of the present application.

In this embodiment, two ends of each of the metal windings extend from two side surfaces of the groove to a surface of the substrate respectively, such as to form 2N metal bonding parts symmetrically distributed on both sides of the surface of the groove, where N is a positive integer greater than 1. That is, one end of each metal winding may extend to form N metal bonding parts, thus implementing a multilayer winding.

It should be noted that N metal bonding parts located on the same side of the surface of the groove may be distributed on the same surface. For example, in the embodiment as shown FIG. 4, where N is 2, each metal winding extends to form 4 metal bonding parts, i.e. metal bonding parts 401, 402, 403 and 404, with every 2 metal bonding parts being located on the same side of the surface of the groove and on the same plane.

It should be understood that N metal bonding parts located on the same side of the surface of the groove may also be distributed on different stepped surfaces. For example, in the embodiment shown in FIG. 5, where N is 2, each metal winding extends to form 4 metal bonding parts, i.e. metal bonding parts 501, 502, 503 and 504. Specifically, the metal bonding parts 501 and 502 are located on a same side of the surface of the groove and on different stepped planes, while the metal bonding parts 503 and 504 are located on another same side of the surface of the groove and on different stepped planes.

N=2 is only taken as an example in this embodiment for illustration purpose. It should be understood that N can be any other numerical value in practical applications. For example, N is 3, 4, 5, etc. and correspondingly, each metal winding extends to form 6, 8, 10, etc metal bonding parts with the similar particular structure, which will not be described in detail here.

For ease of understanding, the package structure of the present application will be described in detail by way of a specific example below. Referring to FIG. 6, a sixth embodiment of the package structure of the present application includes:

a substrate 601 and an inductive core body 602;

a groove 603 for holding the inductive core body 602 provided in the substrate 601; and

several metal windings 604 provided at the bottom of the groove 603, wherein the metal windings 604 extend from a side surface of the groove 603 through a connecting hole 605 in the substrate 601 to a surface of the substrate 601 so as to farm several metal bonding parts 606 and the metal bonding parts 606 are distributed on both sides of a surface of the groove 603.

In this embodiment, two ends of each of the metal windings 604 may extend from two side surfaces of the groove 603 to the surface of the substrate 601 respectively, so as to form two metal bonding parts 606 symmetrically distributed on both sides of the surface of the groove 601.

The groove 603 in this embodiment may be obtained by laser-burning or etching the substrate 601, and can also be obtained by other ways, which should be understood and is not limited herein.

The inductive core body 602 in this embodiment may be a magnetic core or ferrite, or be made of other materials. The inductive core body 602 may be fixed in the groove 603 by implanting non-conducting adhesive materials (such as a glue or film) for Die Attach, or may be fixed in the groove 603 by other ways, which will not be specifically limited herein.

In the above arrangement manner, the metal winding 604 may enclose the groove 603 through a bottom surface and two side surfaces, i.e. forming a lower-half metal enclosing structure for the inductive core body 602 in the groove 603. In order to obtain as helical coil of an inductor, a metal lead also needs to be provided on the substrate 601, so as to form an upper-half metal enclosing structure for the inductive core body 602 in the groove 603.

Specifically, the metal bonding parts 606 on both sides of the surface of the groove 603 may be connected by the metal leads 610 so as to form a helical coil, so that a passage is formed between any two connected metal bonding parts.

In practical applications, the substrate in this embodiment may be a substrate with a double-sided circuit layer or a substrate with multiple circuit layers. Specifically, the structure of the substrate with a double-sided circuit layer may include:

a first ink layer 607a, a second ink layer 607b, a first circuit layer 608a, a second circuit layer 608b and a core board layer 609 being an insulating layer; wherein

the groove 603 is located in the core board layer 609;

the metal windings 604 are located at the second circuit layer 608b at the bottom of the core board layer 609, the metal bonding parts 606 are located at the first circuit layer 608a at the top of the core board layer 609;

the connecting holes 605 extend through the core board layer 609 to connect the metal windings 604 and the metal bonding parts 606; and

a surface of the first circuit layer 608a is coated with the first ink layer 607a, and a surface of the second circuit layer 608b is coated with the second ink layer 607b.

It should be noted that, in order to facilitate automatically controlling the inductance amount of an inductor by a chip or an apparatus, several pairs of metal connecting parts connected with the metal bonding parts 606 may also be provided on the substrate 601, so that a controlling apparatus may be electrically connected to the metal connecting parts and thus connected to the helical coil. Therefore, the controlling apparatus may control the length of the helical coil to be used, and thus control the inductance amount output from the helical coil.

In this embodiment, several metal windings 604 are provided at the bottom of the groove 603 for holding the inductive core body 602, and extend from a side surface of the groove 603 through the connecting hole 605 in the substrate 601 to a surface of the substrate 601 so as to form several metal bonding parts 606, enclosing the groove 603. Therefore, when the metal bonding parts 606 on both sides of the surface of the groove 603 are electrically connected, a helical coil may be formed, thus functioning as an inductor.

However, there are a number of metal bonding parts 606, and when different metal bonding parts 606 are connected, the length of the conducting metal windings 604 and thus inductance amounts are different. Users can connect different metal bonding parts 606 depending on the actual requirements to obtain desired inductance amount. Since the embodiment of the present application may meet the user's requirements of various inductance amounts, a packaging space can be saved, thereby improving the integration level and packaging effect of the system.

Second, the first metal enclosing structure is an in-substrate connecting structure, and the second metal enclosing structure is an out-of-substrate connecting structure.

In this embodiment, forming the upper-half metal enclosure for the groove by the first metal enclosing structure is implemented by providing metal windings in the substrate, and forming the lower-half metal enclosure for the groove by the second metal enclosing structure is implemented by bonding metal leads on the surface of the substrate.

Specifically, the first metal enclosing structure includes several metal windings and several metal bonding parts, wherein the metal windings are provided at the top of the groove; the metal bonding parts is formed by extending the metal windings from a side surface of the groove through a connecting hole in the substrate to a surface of the substrate, and the metal bonding parts are distributed on both sides of a surface of the groove; and

correspondingly, the second metal enclosing structure includes several metal leads; and the metal bonding parts on both sides of the surface of the groove are connected by the metal leads, so that a passage is termed between any two connected metal bonding parts.

Third, the first metal enclosing structure is an out-of-substrate connecting structure, and the second metal enclosing structure is an out-of-substrate connecting structure.

In this embodiment, forming the upper-half metal enclosure for the groove by the first metal enclosing structure is implemented by bonding metal leads on the surface of the substrate, and forming the lower-half metal enclosure for the groove by the second metal enclosing structure is also implemented by bonding metal leads on the surface of the substrate.

Specifically, the first metal enclosing structure includes upper surface metal windings, upper surface metal bonding parts and upper surface metal leads, wherein the upper surface metal winding is provided on as side surface of the groove; the upper surface metal bonding part is framed by extending the upper surface metal winding through a connecting hole in the substrate to an upper surface of the substrate, the upper surface metal bonding parts are distributed on both sides of the upper surface of the substrate and the upper surface metal bonding parts on both sides of the upper surface of the substrate are connected by the upper surface metal lead; and

correspondingly, the second metal enclosing structure includes lower surface metal windings, lower surface metal bonding parts and lower surface metal leads, wherein the lower surface metal winding is provided on a side surface of the groove; the lower surface metal bonding part is formed by extending the lower surface metal winding through the connecting hole in the substrate to a lower surface of the substrate, the lower surface metal bonding parts are distributed on both sides of the lower surface of the substrate; and the lower surface metal bonding parts on both sides of the lower surface of the substrate are connected by the lower surface metal lead.

Fourth, the first metal enclosing structure is an in-substrate connecting structure, and the second metal enclosing structure is cart in substrate connecting structure.

In this embodiment, forming the lower-half metal enclosure for the groove by the second metal enclosing structure is implemented by providing metal windings in the substrate, and forming the upper-half metal enclosure for the groove by the first metal enclosing structure is also implemented by providing metal windings in the substrate.

Specifically, the first metal enclosing structure includes as first set of metal windings;

wherein the first set of metal windings are pro Wed at the top of the groove, and enclose the groove from the upper half of the groove;

correspondingly, the second metal enclosing structure includes a set of metal windings;

wherein the second set of metal windings are provide, the bottom of the groove, and enclose the groove from the lower half of the groove; and

the first set of metal windings and the second set of metal windings are mated such that a helical coil is formed around the groove when the first set of metal windings and the second set of metal windings are connected.

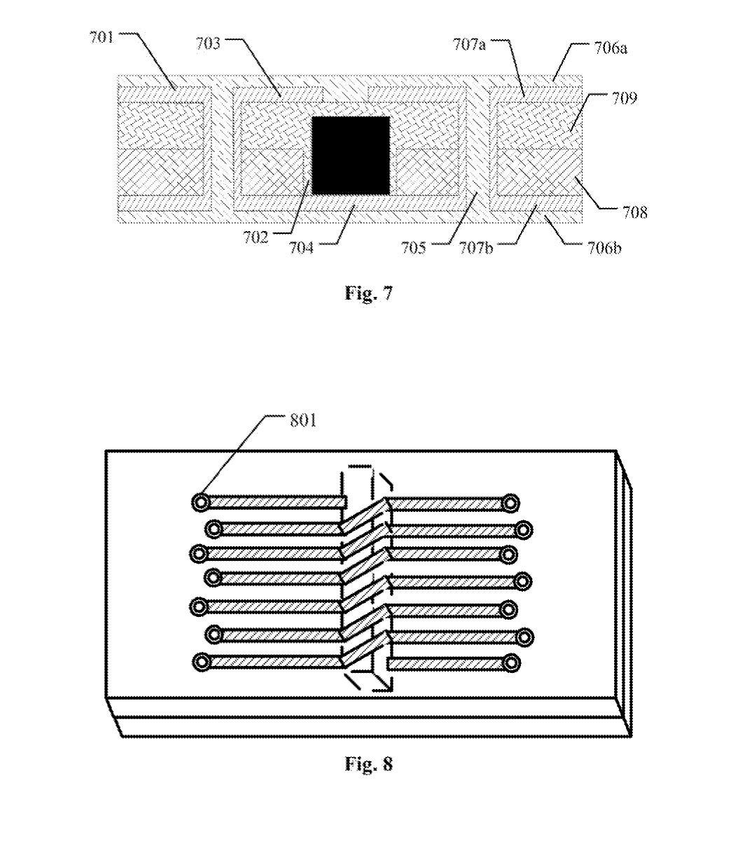

A detailed explanation will be made in conjunction with the accompanying drawings below, Referring to FIG. 7, a seventh embodiment of the package structure of the present application includes:

a substrate 701;

a groove 702 provided in the substrate 701;

a first set of metal windings 703 provided at the top of the groove 702, wherein the first set of metal windings 703 enclose the groove 702 from an upper half of the groove 702;

a second set of metal windings 704 provided at the bottom of the groove 702, wherein the second set of metal windings 704 enclose the groove 702 from an lower half of the groove 702; and

the first set of metal windings 703 and the second set of metal windings 704 are mated such that a helical coil is formed around the groove when the first set of metal windings 703 and the second set of metal windings 704 are connected through a connecting hole 705 in the substrate 701.

The package structure in this embodiment may further include an inductive core body to increase the inductance amount. The inductive core body may be as magnetic core or ferrite, or be made of other materials. The inductive core body may be fixed in the groove 702 by implanting non-conducting adhesive materials (such as a glue or film) for Die Attach, or may be fixed in the groove 702 by other ways, which will not be specifically limited herein.

It should be noted that the substrate 701 may be a substrate with a double-sided circuit layer or a substrate with multiple circuit layers in practical applications. Specifically, the structure of the substrate with a double-sided circuit layer may include:

a first ink layer 706a, a second ink layer 706b, a first circuit layer 707a, a second circuit) layer 707b, a core board layer 708 and a filling layer 709, wherein

the groove 702 is located in the core board layer 708, the core board layer 708 is an insulating layer;

the filling layer 709 is located at the top of the groove 702, the filling layer 709 is an insulating layer;

the first set of metal windings 703 are located at the first circuit layer 707a at the top of the core board layer 708, the second set of metal windings 704 are located at the second circuit layer 707b at the bottom of the core board layer 708;

the connecting hole 705 extends through the core board layer 708 to connect the first set of metal windings 703 and the second set of metal windings 704; and a surface of the first circuit layer 707a is coated with the first ink layer 706a, and a surface of the second circuit layer 707b is coated with the second ink layer 706b.

The package structure formed specifically in this embodiment may seem as shown in FIG. 8. It should be noted that, in order to facilitate automatically controlling the inductance amount of an inductor by a chip or an apparatus, several pairs of metal connecting parts 801 electrically connected with a helical coil may also be provided on the substrate, so that at controlling apparatus may be electrically connected to the metal connecting parts 801 and thus connected to the helical coil. Therefore, the controlling apparatus may control the length of the helical coil to be used, and thus control the inductance amount output from the helical coil.

In this embodiment, the first set of metal windings 703 are provided at the top of the groove 702, and the second set of metal windings 704 are provided at bottom of the groove 702, The first set of metal windings 703 and the second set of metal windings 704 are connected through the connecting hole 705 in the substrate 701 so as to form a helical coil around the groove 702, thus functioning as an inductor.

After the helical coil is formed, users can determine the length of the helical coil connected into a circuit depending on the actual requirements so as to obtain desired inductance amount, Since the embodiments of the present application can meet the user's requirements of various inductance amounts, as packaging space can be saved, thereby improving the integration level and packaging effect of the system.

In the above solution described in conjunction with FIG. 7, the first set of metal windings and the second metal windings are of a single winding structure, that is, the first set of metal windings and the second set of metal windings form as same coil.

It should be understood that in practical applications, in addition to the single winding structure, a multifilar winding structure or a multilayer winding structure may also be possible.

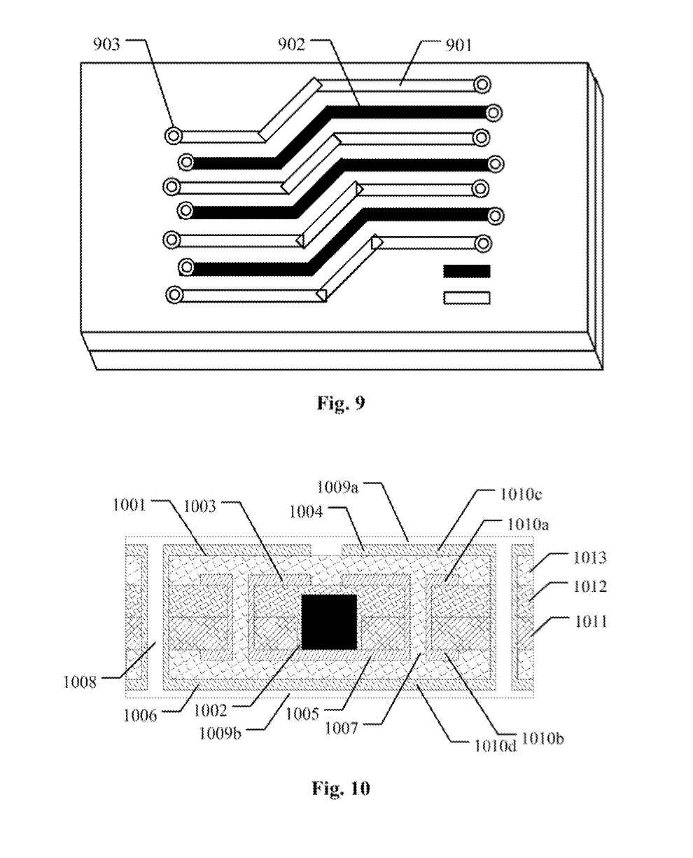

Specifically, in the case of the multifilar winding structure, please make a reference to FIG. 9 showing an eighth embodiment of the package structure or the present application.

The first set of metal windings and the second set of metal windings form two helical coils, i.e. helical coils 901 and 902 as shown in FIG. 9. As such, two different coils are actually provided around the groove. It should be understood that two coils are only used as an example for illustration purpose here, and in practical applications, more coils can be used, which is not limited herein.

In order to facilitate automatically controlling the inductance amount of an inductor by a chip or an apparatus, several pairs of metal connecting parts 903 electrically connected with a helical coil may also be provided on the substrate, so that a controlling apparatus may be electrically connected to the metal connecting parts 903 and thus connected to the helical coil. Therefore, the controlling apparatus may control the length of the helical cod to be used, and thus control the inductance amount output from the helical coil.

In the case of the multilayer winding structure, please make a reference to FIG. 10 showing a ninth embodiment of the package structure of the present application.

The ninth embodiment of the package structure of the present application includes:

a substrate 1001;

a groove 1002 provided in the substrate 1001,

a first set of metal windings 1003 and a third set of metal windings 1004 provided at the top of the groove 1002, wherein the first set of metal windings 1003 and the third set of metal windings 1004 enclose the groove 1002 from an upper half of the groove 1002; and in the embodiment the third set of metal windings 1004 and the first set of metal windings 1003 are located at different circuit layers;

a second set of metal windings 1005 and a fourth set of metal windings 1006 are provided at the bottom of the groove 1002, wherein the second set of metal windings 1005 and the fourth set of metal windings 1006 enclose the groove 1002 from a lower half of the groove 1002; and in this embodiment, the fourth set of metal windings 1006 are located at to circuit layer different from that of the second set of metal windings 1005.

The first set of metal windings 1003 and the second set of metal windings 1005 are mated such that a helical coil is formed around the groove 1002 when the first set of metal windings 1003 and the second set of metal windings 1005 are connected through a first connecting hole 1007 in the substrate 1001.

The third set of metal windings 1004 and the fourth set of metal windings 1006 are mated such that another helical coil is formed around the groove 1002 when the third set of metal windings 1004 and the fourth set of metal windings 1006 are connected through a second connecting hole 1008 in the substrate 1001.

The package structure in this embodiment may further include an inductive core body to increase the inductance amount. The inductive core body may be a magnetic core or ferrite, or be made of other materials. The inductive core body may be fixed in the groove 1002 by implanting non-conducting adhesive materials (such as a glue or film) for Die Attach, or may be fixed in the groove 1002 by other ways, which will not be specifically limited herein.

The substrate 1001 in this embodiment may be a substrate with multiple circuit layers. Specifically, the structure of such a substrate may include:

a first ink layer 1009a, a second ink layer 1009b, a first circuit layer 1010a, a second circuit layer 1010b, a third circuit layer 1010c, a fourth circuit layer 1010d, a core board layer 1011, a first filling layer 1012 and a second filling layer 1013, wherein

the groove 1002 is located in the core board layer 1011 being an insulating layer;

the first filling layer 1012 is located at the top of the groove 1002 and is an insulating layer;

the second filling layer 1013 is located around the groove 1002, and is an insulating layer;

the first set of metal windings 1003 are located at the first circuit layer 1010a at the to of the core board layer 1011, the second set of metal windings 1005 are located at the second circuit layer 1010b at the bottom of the core board layer 1011;

the third set of metal windings 1004 are located at the third circuit layer 1010c at the to of the core board layer 1011, the fourth set of metal windings 1006 are located at the fourth circuit layer 1010d at the bottom of the core board layer 1011;

the first connecting hole 1007 extends through the core board layer 1011 to connect the first set of metal windings 1003 and the second sot of metal windings 1005;

the second connecting hole 1008 extends through the core board layer 1011, the first filling layer 1012 and the second filling layer 1013 to connect the third set of metal windings 1004 and the fourth set of metal windings 1006; and

a surface of the third circuit layer 1010c is coated with the first ink layer 1009a, a surface of the fourth circuit layer 1010d is coated with the second ink layer 1010b.

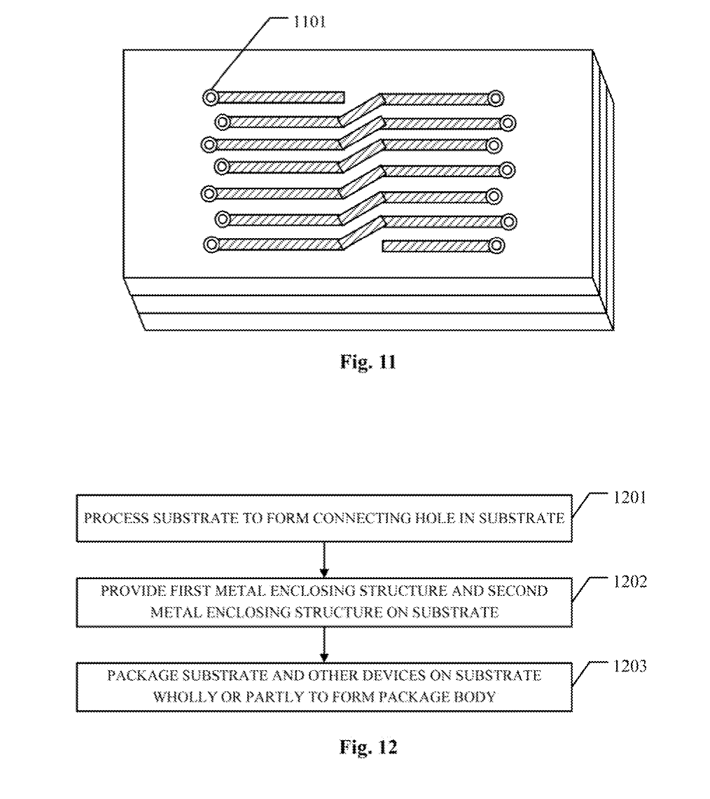

The package structure formed specifically in this embodiment may seem as shown in FIG. 11. It should be noted that, in order to facilitate automatically controlling the inductance amount of ail inductor by a chip or an apparatus, several parts of metal connecting parts 1101 electrically connected with a helical coil may also be provided on the substrate, so that a controlling apparatus may be electrically connected to the metal connecting parts 1101 and thus connected to the helical coil. Therefore, the controlling apparatus may control the length of the helical coil to be used, and thus control the inductance amount output from the helical coil.

It should be noted that in the above embodiments, when the metal windings and the metal leads are of the multifilar winding structure or multilayer winding structure, as plurality of helical coils may be formed, and each helical, coil includes the first metal enclosing structure and the second metal enclosing structure. Four implementations of the first metal enclosing structure and the second metal enclosing structure have been mentioned above, and it should be understood that different helical coils may be implemented in the same manner or in different manners in practical applications.

For example, there are four different helical coils in the multifilar winding structure. The four different helical coils may all be implemented as including “the first metal enclosing structure of an out-of-substrate connecting structure and the second metal enclosing structure of an in-substrate connecting structure”, or including “the first metal enclosing structure of an in-substrate connecting structure and the second metal enclosing structure of an in-substrate connecting structure”, or may all be implemented in other ways. Alternatively, the four different helical coils may be differently implemented. For example, the first and second helical coils include “the first metal enclosing structure of an out-of-substrate connecting structure and the second metal enclosing structure of an in-substrate connecting structure”, and the third and fourth helical coils include “the first metal enclosing structure of an in-substrate connecting structure and the second metal enclosing structure of an in-substrate connecting structure”. The specific implementation is not limited herein.

The package structure in the embodiments of the present application has been described above, and a packaging method in the embodiments of the present application will be described below. Referring to FIG. 12, one embodiment of the packaging method of the present application includes the following steps 1201 to 1203.

In step 1201, a substrate is processed to form a connecting hole in the substrate.

In this embodiment, in order to enable the connection between a first metal enclosing structure and a second metal enclosing structure, the substrate may be processed to form the connecting hole.

Specifically, the substrate may be drilled to form the connecting hole. It should be understood that in practical applications, the substrate may be processed in other ways such as to form the connecting hole, which is not specifically limited herein.

It should be noted that if it is desired to accommodate an inductive core body, a groove for holding the inductive core body may be provided in the substrate. Specifically, the groove may be thrilled by laser-burning or etching the substrate.

It should be understood that the groove may be or lay not be provided in practical applications.

In step 1202, a first metal enclosing structure and a second metal enclosing structure are provided on the substrate.

In this embodiment, the first metal enclosing structure and the second metal enclosing structure may be provided on the substrate, such that the first metal enclosing structure and the second metal enclosing structure are connected through a connecting, hole in the substrate to form a helical coil, thus functioning as an inductor.

In this embodiment, when no groove is provided, the first metal enclosing structure and the second metal enclosing structure are located at the upper portion and the lower portion of the substrate respectively.

When a groove is provided, the first metal enclosing structure may be located at the top of the groove, and the second metal enclosing structure may be located at the bottom of the groove, with the helical coil being formed around the groove.

In practical applications, whether a groove needs to be provided may be determined depending on requirements, and thus the position relationship between the first metal enclosing structure and the second metal enclosing structure may be determined.

In step 1203, the substrate and other devices on the substrate are packaged wholly or partly to form a package body.

After the helical coil is formed, the substrate and other devices on the substrate are packaged wholly or partly to form a package body, or the substrate and the whole system on the substrate are molded together so as to form a package body.

In practical applications, the first metal enclosing structure and the second metal enclosing structure may be implemented in various ways, and accordingly, the packaging method in this embodiment will be varied.

First, the first metal enclosing structure is an out-of-substrate connecting structure. and the second metal enclosing structure is an in-substrate connecting structure.

In this embodiment, forming the lower-half metal enclosure for the groove by the second metal enclosing structure is implemented by providing metal windings in the substrate, and forming the upper-half metal enclosure for the groove by the first metal enclosing structure is implemented by bonding metal leads on the surface of the substrate.

Specifically, the second metal enclosing structure may include several metal windings and several metal bonding parts, wherein the metal windings are provided at the bottom of the groove; and the metal bonding parts are formed by extending the metal windings from a side surface of the groove through a connecting hole in the substrate to a surface of the substrate, and are distributed on both sides of a surface of the groove; and

correspondingly, the first metal enclosing structure may include several metal leads; and the metal bonding parts on both sides of the surface of the groove are connected by the metal leads, so that a passage is formed between any two connected metal bonding parts.

In this embodiment, providing the second metal enclosing structure at the bottom of the groove and providing the first metal enclosing structure at the top of the groove includes:

providing several metal windings at the bottom of the groove, extending the metal windings from a side surface of the groove through the connecting hole in the substrate to a surface of the substrate so as to form several metal bonding parts, wherein the metal bonding parts are distributed on both sides of a surface of the groove; and

connecting the metal bonding parts on both sides of the surface of the groove by using the metal leads to form at helical coil, so that a passage is formed between any two connected metal bonding parts.

Second, the first metal enclosing structure is an in-substrate connecting structure, and the second metal enclosing structure is an out-of-substrate connecting structure.

In this embodiment, forming the upper-half metal enclosure for the groove by the first metal enclosing structure is implemented by providing metal windings in the substrate, and forming the lower-half metal enclosure for the groove by the second metal enclosing structure is implemented by bonding metal leads on the surface of the substrate.

Specifically, the first metal enclosing structure includes several metal windings and several metal bonding parts, wherein the metal windings are provided at the top of the groove; the metal bonding parts is formed by extending the metal windings from a side surface of the groove through a connecting hole in the substrate to a surface of the substrate, and the metal bonding parts are distributed on both sides of a surface of the groove; and

correspondingly, the second metal enclosing structure includes several metal leads; and the metal bonding parts on both sides of the surface of the groove are connected by the metal leads, so that a passage is formed between any two connected metal bonding parts.

In this embodiment, providing the second metal enclosing structure at the bottom of the groove and providing the first metal enclosing structure at the top of the groove includes:

providing several metal windings at the bottom of the groove, extending the metal windings from a side surface of the groove through the connecting hole in the substrate to it surface of the substrate so as to form several metal bonding parts, wherein the metal bonding parts are distributed on both sides of a surface of the groove; and

connecting the metal bonding parts on both sides of the surface of the groove by using the metal leads to form a helical coil, so that a passage is formed between any two connected metal bonding parts.

Third, the first metal enclosing structure is an out-of-substrate connecting structure, and the second metal enclosing structure is an out-of-substrate connecting structure.

In this embodiment, forming the upper-half metal enclosure for the groove by the first metal enclosing structure is implemented by bonding metal leads on the surface of the substrate, and forming the lower-hall metal enclosure for the groove by the second metal enclosing structure is also implemented by bonding metal leads on the surface of the substrate.

Specifically, the first metal enclosing structure includes upper surface metal windings, upper surface metal bonding parts and upper surface metal leads, wherein the upper surface metal winding is provided on a side surface of the groove; the upper surface metal bonding part is formed by extending the upper surface metal winding through a connecting hole in the substrate to an upper surface of the substrate, the upper surface metal bonding parts are distributed on both sides of the upper surface of the substrate; and the upper surface metal bonding parts on both sides of the upper surface of the substrate are connected by the upper surface metal lead; and

correspondingly, the second metal enclosing structure includes lower surface metal windings, lower surface metal banding parts and lower surface metal leads, wherein the lower surface metal winding is provided on a side surface of the groove; the lower surface metal bonding part is formed by extending the lower surface metal winding through the connecting hole in the substrate to a lower surface of the substrate, the lower surface metal bonding parts are distributed on both sides of the lower surface of the substrate; and the lower surface metal bonding parts on both sides of the lower surface of the substrate are connected by the lower surface metal lead.

In this embodiment, providing the second metal enclosing structure at the bottom of the groove and providing the first metal enclosing structure at the top of the groove includes:

providing the upper surface metal windings on a side surface of the groove, extending the upper surface metal windings through the connecting hole in the substrate to an upper surface of the substrate so as to form the upper surface metal bonding parts, wherein the upper surface metal bonding parts are distributed on both sides of the upper surface of the substrate;

connecting the upper surface metal bonding parts on both sides of the upper surface of the substrate by using the tipper surface metal leads;

providing the lower surface metal windings on a side surface of the groove, extending the lower surface metal windings through the connecting hole in the substrate to a lower surface of the substrate so as to form the lower surface metal bonding parts, wherein the lower surface metal bonding parts are distributed on both sides of the lower surface of the substrate; and

connecting the lower surface metal bonding parts on both sides of the lower surface of the substrate by using the lower surface metal leads.

Fourth, the first metal enclosing structure is an in-substrate connecting structure, and the second metal enclosing structure is an in-substrate connecting structure.

In this embodiment, forming the lower-half metal enclosure for the groove by the second metal enclosing structure is implemented by providing metal windings in the substrate, and forming the upper-half metal enclosure for the groove by the first metal enclosing structure is also implemented by providing metal windings in the substrate.

Specifically, the first metal enclosing structure includes a first set of metal windings;

wherein the first set of metal windings are provided at the top of the groove, and enclose the groove from the upper half of the groove;

correspondingly, the second metal enclosing structure includes a second set of metal windings;

wherein the second set of metal windings are provided at the bottom of the groove, and enclose the groove from the lower half of the groove; and

the first set of metal windings and the second set of metal windings are mated such that a helical coil is formed around the groove when the first set of metal windings and the second set of metal windings are connected.

In this embodiment, providing the second metal enclosing structure at the bottom of the groove and providing the first metal enclosing structure at the top of the groove includes:

providing the first set of metal windings at the top of the groove so that the first set of metal windings enclose the groove from the upper half of the groove, and providing the second set of metal windings at the bottom of the groove so that the second set of metal windings enclose the groove from the lower half of the groove; and

mating the first set of metal windings with the second set of metal windings, so that a helical coil is formed around the groove when the first set of metal windings and the second set of metal windings are connected.

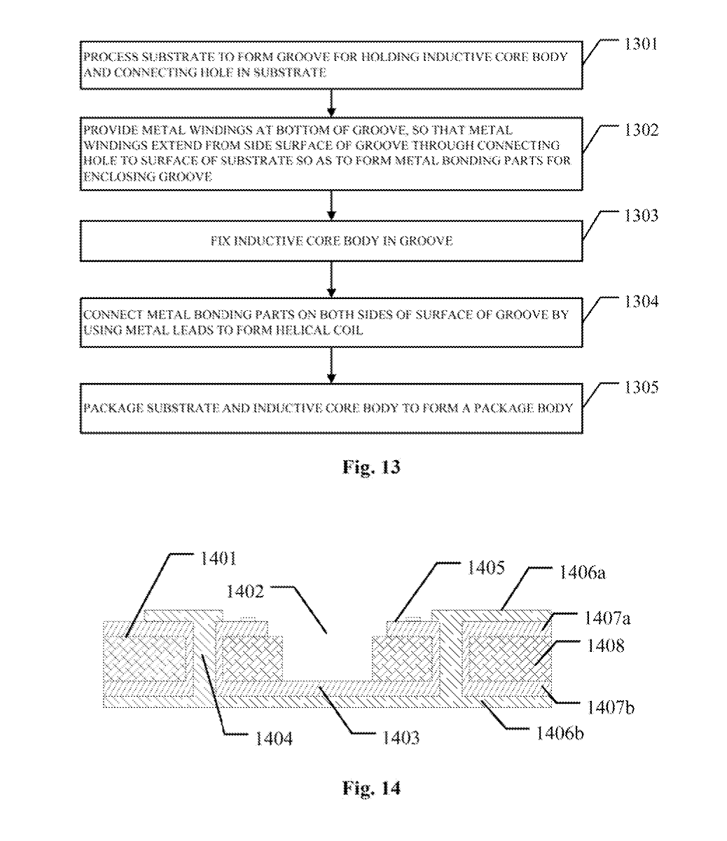

For understanding with ease, a packaging process of the present application will be described in detail by taking the above first mode as an example below. Referring to FIG. 13, another embodiment of the packaging process of the present application includes the following steps 1301 to 1305.

In step 1301, a substrate is processed to form a groove for holding an inductive core body and a connecting hale in the substrate.

In this embodiment, in order to accommodate the inductive core body and facilitate wiring to form a metal bonding part, the substrate needs to be processed to form the groove and the connecting hole in the substrate.

Specifically, the groove may be formed by laser-burning or etching the substrate, and the connecting hole may be famed by drilling the substrate. It should be understood that the groove and the connecting hole can be formed by processing the substrate in other ways in practical applications, which will not be specifically limited herein.

In step 1302, several metal windings are provided at the bottom of the groove, so that the metal windings extend from a side surface of the groove through the connecting hole in the substrate to a surface of the substrate so as to form several metal bonding parts, thereby enclosing the groove.

In this embodiment, after the groove is formed, several metal windings may be provided at the bottom of the groove, so that the metal windings extend through the connecting hole in the substrate from a side surface of the groove to a surface of the substrate so as to form several metal bonding parts, thereby enclosing the groove, The metal bonding parts are distributed on both sides of a surface of the groove.

A package structure formed after this step is performed may seem as shown in FIG. 14, and specifically includes:

a first ink layer 1406a, a second ink layer 1406b, a first circuit layer 1407a, a second circuit layer 1407b and a core board layer 1408, wherein

the groove 1402 is located in the core board layer 1408 being an insulating layer;

the metal windings 1403 are located at the second circuit layer 1407b at the bottom of the core board layer 1408, the metal bonding parts 1405 are located at the first, circuit layer 1407a at the top of the core board layer 1408;

the connecting hole 1404 extends through the core board layer 1408 to connect the metal windings 1403 and the metal bonding parts 1405; and

a surface of the first circuit layer 1407a is coated with the first ink layer 1406a, and a surface of the second circuit layer 1407b is coated with the second ink layer 1406b.

The metal windings and the metal leads in this embodiment may be of a single winding structure, a multifilar winding structure or a multilayer winding structure.

Specifically, when the metal windings and the metal leads are of the single winding structure,

the metal windings provided at the bottom of the groove all form the same helical coil, and two ends of each of the metal windings extend from two side surfaces of the groove to a surface of the substrate, so as to form two metal bonding parts symmetrically distributed on both sides of the surface of the groove. That is, all of the metal windings and the metal leads form the same coil.

When the metal windings and the metal leads are of the multifilar winding structure,

the metal windings provided at the bottom of the groove form different helical coils, and two ends of each of the metal windings extend from two side surfaces of the groove to a surface of the substrate respectively, so as to form two metal bonding parts symmetrically distributed on both sides of the surface of the groove, that is, there are two different coils around the groove. It should be understood that two coils are only used as an example for illustration purpose here, and more coils can be used in practical applications, which is not limited herein.

When the metal windings and the metal leads are of the multilayer winding structure,

two ends of each of the metal windings extend from two side surfaces of the groove to a surface of the substrate respectively, so as to form 2N metal bonding parts symmetrically distributed on both sides of the surface of the groove, where N is a positive integer, and N metal bonding parts located on the same side of the surface of the groove are distributed on the same surface or distributed on different stepped surfaces. That is, one end of each metal winding may extends to form N metal bonding parts, thus resulting in a multilayer winding.

In step 1303, the inductive core body is fixed in the groove.

After the substrate is formed, the inductive core body may be fixed in the groove. The inductive core body in this embodiment may be a magnetic core or ferrite, or be made or other materials. The inductive core body may be fixed in the groove by implanting non-conducting adhesive materials (such as glue or film) for Die Attach, or may be fixed in the groove by other ways, which will not be specifically limited herein.

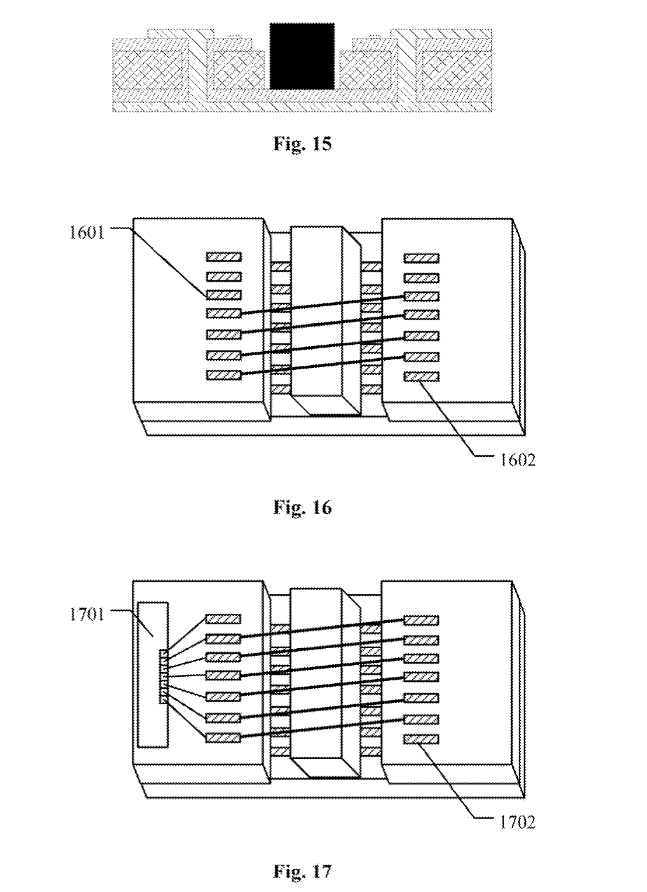

A package structure after the inductive core body is fixed may seem as shown in FIG. 15, and the particular structure will not be repeatedly described here.

It should be understood that the inductance amount may be increased by inserting an inductive core body. If there is no need for a large inductance amount in a practical application, the inductive core body may also not be inserted, and step 1303 may not be performed.

In step 1304, the metal bonding parts on both sides of the surface of the groove are connected by using the metal leads so as to form a helical coil.

In this embodiment, by using the metal leads, the metal bonding parts on both sides of the surface of the groove may be connected to form a helical coil, so that a passage is formed between any two connected metal bonding parts. A package structure formed may seem as shown in FIG. 6, and the particular structure will not be repeatedly described here.

In step 1305, the substrate and the inductive core body are packaged to form a package body.

After the metal leads are connected, the inductor part may be glue-scaled to be protected, or may be molded together with the whole system on the substrate into a package body.

It should be noted that, if no inductive core body is inserted, the substrate and other devices packaged thereon are packaged to form a package body, or are molded together with the whole system on the substrate to form a package body.

In order to facilitate automatically controlling the inductance amount of an inductor by a chip or an apparatus, several pairs of metal connecting parts connected with the metal bonding parts 606 may also be provided on the substrate 601, so that a controlling apparatus may be electrically connected to the metal connecting, parts and thus connected to the helical coil. Therefore, the controlling apparatus may control the length of the helical coil to be used, and thus control the inductance amount output from the helical coil.

In this embodiment, several metal windings 604 are provided at the bottom of the groove 603 for holding the inductive core body 602, and extend from a side surface of the groove 603 through the connecting hole 605 in the substrate 601 to a surface of the substrate 601 so as to form several metal bonding parts 606, enclosing the groove 603. Therefore, when the metal bonding parts 606 on both sides of the surface of the groove 603 are electrically connected, a helical coil may be formed, thus functioning as an inductor.

However, there are a number of metal bonding parts, and when different metal bonding parts are connected, the length of the conducting metal windings and thus inductance amounts are different. Users can connect different metal bonding parts depending on the actual requirements to obtain desired inductance amount. Since the embodiment of the present application may meet the user's requirements of various inductance amounts, a packaging space can be saved, thereby improving the integration level and packaging effect of the system.

For understanding with ease, the application of the package structure of the present application will be described by way of several particular application examples below.

Referring to FIG. 16, a first application scene of the package structure of the present application is to manually adjust an inductance amount.

In this embodiment, the metal leads on the surface of the groove are connected in a skew manner.

When a specific inductance amount is desired, a user may connect different metal leads voluntarily. The greater the number of the connected metal leads is, the greater the inductance amount is and the smaller the number of the connected metal leads is, the smaller the inductance amount is, where a metal bonding part 1601 and a metal bonding part 1602 are two ends of an inductor respectively.

Referring to FIG. 17, a second application scene of the package structure of the present application is to automatically adjust an inductance amount.

In this embodiment, metal leads on a surface of as groove are connected in as skew manner.

Every pair of metal bonding parts are connected by a metal lead, and a metal bonding part 1702 is one end of an inductor.

The metal bonding parts on the left are connected to a controlling device 1701. through a gold finger or welding pad, and based on the currently desired inductance amount, the controlling device 1701 may determine which metal bonding part on the left is used as the other end of an inductor. The farther the distance between the selected metal bonding part and the meta bonding part 1702 is, the greater the inductance amount is; and the nearer the distance between the selected metal bonding part and the metal bonding part 1702 is, the smaller the inductance amount is.

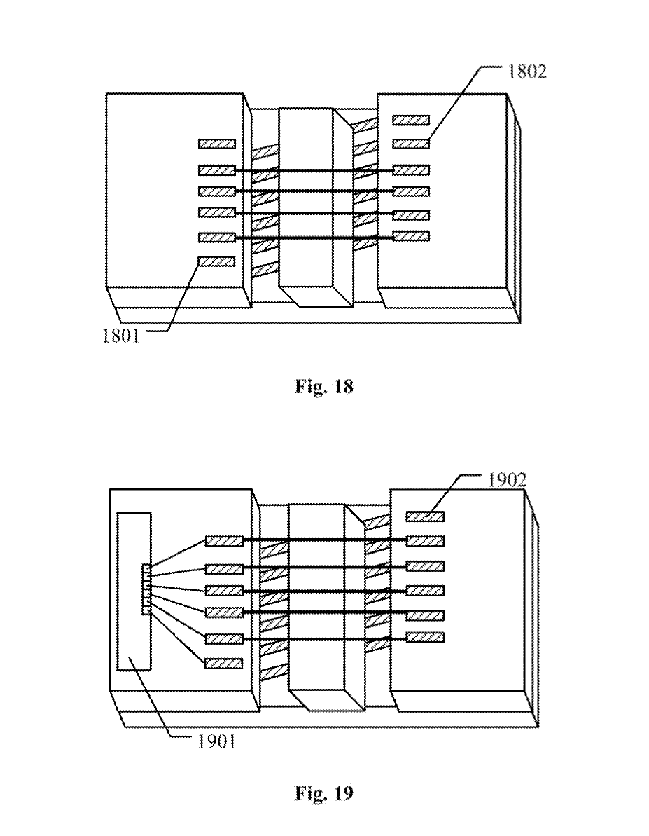

Referring to FIG. 18, a third application scene of the package structure of present application is to manually adjust an inductance amount.

In this embodiment, metal windings at the bottom of a groove are provided in a skew manner.

When a specific inductance amount is desired, a user may connect different metal leads voluntarily. The greater the number of the connected metal leads is, the eater the inductance amount is; and the smaller the number of the connected metal leads is, the smaller the inductance amount is, where a metal bonding part 1801 and a metal bonding part 1802 are two ends of an inductor respectively.

Referring to FIG. 19, a fourth application scene of the package structure of the present application is to automatically adjust an inductance amount.

In this embodiment, metal windings at the bottom of a groove are provided in a skew manner.

Every pair of metal bonding parts are connected by a metal lead, and a metal bonding part 1902 is one end of an inductor.

The metal bonding parts on the left are connected to a controlling device 1901 through a gold finger or welding pad, and based on the currently desired inductance amount, the controlling device 1901 may determine which metal bonding part on the left is used as the other end of an inductor. The farther the distance between the selected metal bonding part and the metal bonding part 1902 is, the greater the inductance amount is; and the nearer the distance between the selected metal bonding part and the metal bonding part 1902 is, the smaller the inductance amount is.

It can be seen from the above various application scenes that in this embodiment, there are a number of metal bonding parts, and when different metal bonding parts are connected, the length of the conducting metal windings and thus inductance amounts are different. Users can connect different metal bonding parts depending on the actual requirements to obtain desired inductance amount. Since the embodiment of the present application may meet the user's requirements of various inductance amounts, a packaging space can be saved, thereby improving the integration level and packaging effect of the system.

The above description and the above embodiments are only used to illustrate the technical solutions of the present application, but not to limit them. Though the present application has been illustrated in detail with reference to the aforesaid embodiments, it should be understood by those skilled in the art that any modification may be made to the technical solutions in the aforesaid various embodiments, an equivalent alternative may be made to some technical features of the technical solutions. However, these modifications and alternatives will not cause the nature of the corresponding technical solution to depart from the spirit and scope of the technical solutions in various embodiments at the present application.

1. A package structure, comprising a substrate;
wherein a first metal enclosing structure and a second metal enclosing structure are provided on the substrate; and
the first metal enclosing structure and the second metal enclosing structure are connected through a connecting hole in the substrate to form a helical coil.

2. The package structure according to claim 1, wherein
a groove is further provided in the substrate;
the first metal enclosing structure is located at the top of the groove, and the second metal enclosing structure is located at the bottom of the groove; and
the helical coil is formed around the groove.

3. The package structure according to claim 2, wherein
the second metal enclosing structure comprises a plurality of metal windings and a plurality of metal bonding parts;
the metal windings are provided at the bottom of the groove;
the metal bonding parts is formed by extending the metal windings from a side surface of the groove through the connecting hole in the substrate to a surface of the substrate, the metal bonding parts are distributed on both sides of a surface of the groove;
the first metal enclosing structure comprises a plurality of metal leads; and
the metal bonding parts on both sides of the surface of the groove are connected by the metal leads, so that a passage is formed between any two connected metal bonding parts.

4. The package structure according to claim 3, wherein
the metal windings provided at the bottom of the groove all are parts of the same helical coil, and
two ends of each of the metal windings extend from two side surfaces of the groove to the surface of the substrate respectively, so as to form two metal bonding parts symmetrically distributed on both sides of the surface of the groove;
or
the metal windings provided at the bottom of the groove are parts of different helical coils, and two ends of each of the metal windings extend from two side surfaces of the groove to the surface of the substrate respectively, so as to form two metal bonding parts symmetrically distributed on both sides of the surface of the groove.

5. (canceled)

6. The package structure according to claim 3, wherein
two ends of each of the metal windings extend from two side surfaces of the groove to the surface of the substrate respectively, so as to form 2N metal bonding parts symmetrically distributed on both sides of the surface of the groove, where N is a positive integer greater than 1; and
N metal bonding parts located on the same side of the surface of the groove are distributed on the same surface or distributed on different stepped surfaces.

7. The package structure according to claim 3, wherein
the substrate comprises a first ink layer, a second ink layer, a first circuit layer, a second circuit layer and a core board layer;
the groove is located in the core board layer, the core board layer is an insulating layer;
the metal windings are located at the second circuit layer at the bottom of the core board layer, the metal bonding parts are located at the first circuit layer at the top of the core board layer;
the connecting hole extends through the core board layer to connect the metal windings and the metal bonding parts; and
a surface of the first circuit layer is coated with the first ink layer, a surface of the second circuit layer is coated with the second ink layer.

8. The package structure according to claim 2, wherein
the first metal enclosing structure comprises a plurality of metal windings and a plurality of metal bonding parts;
the metal windings are provided at the top of the groove;
the metal bonding parts are thrilled by extending the metal windings from the side surface of the groove through the connecting hole in the substrate to the surface of the substrate, the metal bonding parts are distributed on both sides of the surface of the groove;
the second metal enclosing structure comprises a plurality of metal leads; and
the metal bonding parts on both sides of the surface of the groove are connected by the metal leads, so that a passage is formed between any two connected metal bonding parts.

9. The package structure according to claim 2, wherein
the first metal enclosing structure comprises upper surface metal windings, upper surface metal bonding parts and upper surface metal leads;
the upper surface metal windings are provided on side surfaces of the groove;
the upper surface metal bonding parts are formed by extending the upper surface metal windings through the connecting hole in the substrate to an upper surface of the substrate, the upper surface metal bonding parts are distributed on both sides of the upper surface of the substrate;
the upper surface metal bonding parts on both sides of the upper surface of the substrate are connected by the upper surface metal leads;
the second metal enclosing structure comprises lower surface metal windings, lower surface metal bonding parts and lower surface metal leads;
the lower surface metal windings are provided on side surfaces of the groove;
the lower surface metal bonding parts are formed by extending the lower surface metal windings through the connecting hole in the substrate to a lower surface of the substrate, the lower surface metal bonding parts are distributed on both sides of the lower surface of the substrate; and
the lower surface metal bonding parts on both sides of the lower surface of the substrate are connected by the lower surface metal leads.

10. The package structure according to claim 2, wherein
the first metal enclosing structure comprises a first set of metal windings;
the first set of metal windings are provided at the top of the groove, and enclose the groove from an upper half of the groove;
the second metal enclosing structure comprises a second set of metal windings:
the second set of metal windings are provided at the bottom of the groove, and enclose the groove from a lower half of the groove; and
the first set of metal windings and the second set of metal windings are mated such that a helical coil is framed around the groove when the first set of metal windings and the second set of metal windings are connected.

11. The package structure according to claim 10, wherein
the same helical coil or at least two helical coils are formed when the first set of metal windings and the second set of metal windings are connected.

12. The package structure according to claim 10, wherein
the first metal enclosing structure further comprises at least a third set of metal windings located at as circuit layer different from that of the first set of metal windings;
the third set of metal windings are provided at the top of the groove, and enclose the groove from the upper half of the groove;
the second metal enclosing structure further comprises at least a fourth set of metal windings located at a circuit layer different from that of the second set of metal windings;
the fourth set of metal windings are provided at the bottom of the groove, and enclose the groove from the lower half of the groove; and
the third set of metal windings and the fourth set of metal windings are mated such that another helical coil is formed around the groove when the third set of metal windings and the fourth set of metal windings are connected.

13. The package structure according to claim 10, wherein
the substrate comprises a first ink layer, a second in layer, a first circuit layer, a second circuit layer, a core board layer and a filling layer;
the groove is located in the core board layer, the core heard layer is an insulating layer;
the filling layer is located at the top of the groove, the filling layer is an insulating layer;
the first set of metal windings are located at the first circuit layer at the top of the core board layer, the second set of metal windings are located at the second circuit layer at the bottom of the core board layer;
the connecting hole extends through the core board layer to connect the first set of metal windings and the second set of metal windings; and
a surface of the first circuit layer is coated with the first ink layer, a surface of the second circuit layer is coated with the second ink layer.

14. The package structure according to claim 1, wherein
a plurality of pairs of metal connecting parts electrically connected with the helical coil are provided on a surface of the substrate;
a controlling apparatus is provided on the substrate; and
the controlling apparatus is connected to the metal connecting parts so as to control the inductance amount output form the helical coil.

15. (canceled)

16. The package structure according to claim 1, further comprising:
an inductive core body provided in the groove.

17. A packaging method, comprising:
processing a substrate to form a connecting hole in the substrate;
providing a first metal enclosing structure and a second metal enclosing structure on the substrate,
wherein the first metal enclosing structure and the second metal enclosing structure are connected through the connecting hole in the substrate form a helical coil; and
packaging the substrate and other devices on the substrate wholly or partly to form a package body.

18. The packaging method according to claim 17, further comprising:
processing the substrate to form a groove in the substrate;
wherein providing a first metal enclosing structure and a second metal enclosing structure on the substrate comprises:
providing the second metal enclosing structure at the bottom of the groove, and providing the first metal enclosing structure at the top of the groove; and
wherein the helical coil is formed around the groove.

19. The packaging method according to claim 18, wherein
the second metal enclosing structure comprises a plurality of metal windings and a plurality of metal bonding parts, and the first metal enclosing structure comprises a plurality of metal leads;
providing the second metal enclosing structure at the bottom of the groove and providing the first metal enclosing structure at the top of the groove comprises:
providing a plurality of metal windings at the bottom of the groove, extending the metal windings from a side surface of the groove through the connecting hole in the substrate to a surface of the substrate so as to form a plurality of metal bonding parts, wherein the metal bonding parts are distributed on both sides of a surface of the groove; and
connecting the metal bonding parts on both sides of the surface of the groove by using the metal leads to form a helical coil, so that a passage is formed between any two connected metal bonding parts.

20. The packaging method according to claim 18, wherein
the first metal enclosing structure comprises a plurality of metal windings and a plurality of metal bonding parts, and the second metal enclosing structure comprises a plurality of metal leads;
providing the second metal enclosing structure at the bottom of the groove and providing the first metal enclosing structure at the top of the groove comprises:
providing a plurality of metal windings at the top of the groove, extending the metal windings from a side surface of the groove through the connecting hole in the substrate to a surface of the substrate so as to form a plurality of metal bonding parts, wherein the metal bonding parts are distributed on both sides of a surface of the groove; and
connecting the metal bonding parts on both sides of the surface of the groove by using the metal leads to form a helical coil, so that a passage is formed between any two connected metal bonding parts.

21. The packaging method according to claim 18, wherein
the first metal enclosing structure comprises upper surface metal windings, upper surface metal bonding parts and upper surface metal leads; the second metal enclosing structure comprises lower surface metal windings, lower surface metal bonding parts and lower surface metal leads;
providing the second metal enclosing structure at the bottom of the groove and providing the first metal enclosing structure at the top of the groove comprises:
providing the upper surface metal windings on side surfaces of the groove, extending the upper surface metal windings through the connecting hole in the substrate to an upper surface of the substrate so as to form the upper surface metal bonding parts, wherein the upper surface metal bonding parts are distributed on both sides of the upper surface of the substrate;
connecting, the upper surface metal bonding parts on both sides of the upper surface of the substrate by using the upper surface metal leads;
providing the lower surface metal windings on side surfaces of the groove, extending the lower surface metal windings through the connecting hole in the substrate to a lower surface of the substrate so as to form the lower surface metal bonding parts, wherein the lower surface metal bonding parts are distributed on both sides of the lower surface of the substrate; and
connecting the lower surface metal bonding parts on both sides of the lower surface of the substrate by using the lower surface metal leads.

22. The packaging method according to claim 18, wherein
the first metal enclosing structure comprises a first set of metal windings, he second metal enclosing structure comprises to second set of metal windings;
providing the second metal enclosing structure at the bottom of the groove and providing the first metal enclosing structure at the top of the groove comprises:
providing the first set of metal windings at the top of the groove, so that the first set of metal windings enclose the groove from the upper half of the groove, and providing the second set of metal windings at the bottom of the groove, so that the second set of metal windings enclose the groove from the lower half of the groove;
wherein the first set of metal windings and the second set of metal windings are mated such that a helical coil is formed around the groove when the first set of metal windings and the second set of metal windings are connected.

23-25. (canceled)
